(19) United States
(12) Patent Application Publication
(10) Pub. No.: US 2021/0202913 A1
(43) Pub. Date: Jul. 1, 2021

(54) LIGHT EXTRACTION APPARATUS AND FLEXIBLE OLED DISPLAYS

(71) Applicant: Corning Incorporated, Corning, NY (US)

(72) Inventors: Bradley Frederick Bowden, Corning, NY (US); Dmitri Vladislavovich Kuksenkov, Elmira, NY (US)

(21) Appl. No.: 17/056,492

(22) PCT Filed: May 15, 2019
(86) PCT No.: PCT/US2019/032491

§ 371 Date: Nov. 18, 2020

Related U.S. Application Data
(60) Provisional application No. 62/673,281, filed on May 18, 2018.

(51) Int. Cl. H01L 51/52; H01L 51/00; H01L 51/56

(52) U.S. Cl. CPC H01L 51/5271; H01L 51/0097; H01L 51/5275; H01L 2251/5338; H01L 51/56

(57) ABSTRACT

A light extraction apparatus includes a flexible substrate, an OLED supported by the flexible substrate, a flexible barrier film, a tapered reflector, and an index-matching layer. The tapered reflector includes at least one side surface, a top surface coupled to the flexible barrier film, and a bottom surface. The top surface is larger in surface area than the bottom surface. The index-matching layer is coupled between a top surface of the OLED and the bottom surface of the tapered reflector. Light emitted from the top surface of the OLED passes through the index-matching layer and into the tapered reflector. The at least one side surface of the tapered reflector includes a slope to redirect the light by reflection into an escape cone and out of the top surface of the tapered reflector.

This application claims the benefit of priority under 35 U.S.C. § 119 of U.S. Provisional Application Ser. No. 62/673,281 filed on May 18, 2018 the content of which is relied upon and incorporated herein by reference in its entirety.

### BACKGROUND

### Field

The present disclosure relates generally to organic light-emitting diode (OLED) displays. More particularly, it relates to flexible OLED displays and apparatus and methods for light extraction from flexible OLED displays.

### Technical Background

OLEDs typically include a substrate, a first electrode, one or more OLED light-emitting layers, and a second electrode. OLEDs can be top-emitting or bottom-emitting. A top-emitting OLED may include a substrate, a first electrode, an OLED structure having one or more OLED layers, and a second transparent electrode. The one or more OLED layers of the OLED structure may include an emission layer and can also include electron and hole injection layers and electron and hole transport layers.

Light emitted by the OLED structure is trapped by total internal reflection (TIR) wherever it passes from a layer with a higher refractive index to a layer with a lower refractive index, for example from the OLED structure that typically has a refractive index in the 1.7-1.8 range to a glass substrate that typically has an index of approximately 1.5, or from a glass substrate to air that has an index of 1.0.

To form a display, the OLEDs may be arranged on a display substrate and covered with an encapsulation layer. However, the light emitted from the top of the OLEDs will once again be subject to TIR from the upper surface of the encapsulation layer even if the space between the encapsulation layer and the OLEDs is filled with a solid material. This further reduces the amount of OLED-generated light available for use in the OLED display.

### SUMMARY

Some embodiments of the present disclosure relate to a light extraction apparatus for a flexible organic light-emitting diode (OLED) display. The light extraction apparatus includes a flexible substrate, an OLED supported by the flexible substrate, a flexible barrier film, a tapered reflector, and an index-matching layer. The tapered reflector includes at least one side surface, a top surface coupled to the flexible barrier film, and a bottom surface. The top surface is larger in surface area than the bottom surface. The index-matching layer is coupled between a top surface of the OLED and the bottom surface of the tapered reflector. Light emitted from the top surface of the OLED passes through the index-matching layer and into the tapered reflector. The at least one side surface of the tapered reflector includes a slope to redirect the light by reflection into an escape cone and out of the top surface of the tapered reflector.

Yet other embodiments of the present disclosure relate to a flexible OLED display. The OLED display includes a flexible substrate supporting an array of OLEDs, an array of tapered reflectors, and a flexible barrier film. Each OLED of the array of OLEDs has a top surface through which light is emitted. Each tapered reflector of the array of tapered reflectors is aligned with an OLED of the array of OLEDs. Each tapered reflector of the array of tapered reflectors includes at least one side surface, a top surface, and a bottom surface coupled to the top surface of a respective OLED of the array of OLEDs. The top surface of each tapered reflector is larger in surface area than the bottom surface of each tapered reflector. The flexible barrier film is coupled to the top surface of each tapered reflector of the array of tapered reflectors.

Yet other embodiments of the present disclosure relate to a method for fabricating a flexible OLED display. The method includes applying a first release layer on a first glass substrate, applying a flexible substrate on the first release layer, and forming an array of OLEDs on the flexible substrate. The method includes applying a second release layer on a second glass substrate, applying a flexible barrier film on the second release layer, and forming an array of tapered reflectors on the flexible barrier film. Each tapered reflector of the array of tapered reflectors includes at least one side surface, a top surface coupled to the flexible barrier film, and a bottom surface. The top surface is larger than the bottom surface. The method includes applying the second substrate, the second release layer, the flexible barrier film, and the array of tapered reflectors to the array of OLEDs such that the bottom surface of each tapered reflector of the array of tapered reflectors is coupled to an OLED of the array of OLEDs.

OLED displays including the light extraction apparatus disclosed herein significantly improve the out-coupling of light from the displays and increase the efficiency and peak brightness of the displays. The external efficiency of flexible OLED displays may be increased by a factor of 100% compared to displays not including the light extraction apparatus. Due to the increased external efficiency, the pixels of the display may be driven with less current for the same brightness, which increases the useful lifetime of the display and reduces the “burn-in” effect. Alternatively, or in addition, the pixels of the display may generate a higher peak brightness, which enables a high dynamic range (HDR). These capabilities are achieved while increasing the overall thickness of the displays by a few tens of microns, which leaves the displays flexible. In addition, the light extraction apparatus does not introduce optical scattering (i.e., haze) that can reduce sharpness and contrast. Further, the light extraction apparatus does not scramble the polarization state of light and is therefore compatible with the use of circular polarizers to reduce ambient light reflection.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1A is a top-down view of an exemplary OLED display that employs the light-extraction apparatus and methods disclosed herein;

FIG. 1B is a top-down close-up view of an array of four OLEDs illustrating example dimensions of the OLEDs and the OLED array formed by the OLEDs;

FIG. 1C is a close-up x-z cross-sectional view of a section of the OLED display of FIG. 1A;

FIG. 1D is an even more close-up view of the section of the OLED display shown in FIG. 1C, and includes a close-up inset showing a basic layered OLED structure;

FIG. 2 is an elevated exploded view of an exemplary light-emitting apparatus formed by the OLED, the index-matching material and the tapered reflector, wherein the tapered reflector and index-matching material constitute a light extraction apparatus;

FIG. 3 is a top-down view of four OLEDs and four tapered reflectors arranged one on each OLED;

FIGS. 4A and 4B are side views of example shapes for the tapered reflectors;

FIG. 4C is a plot of an example complex surface shape for a side of the tapered reflector, wherein the shape ensures that all of the light emitted by the OLED into the body of the tapered reflector and not directly hitting the top surface is subjected to total internal reflection at the side surface of the tapered reflector;

FIG. 4D is a schematic illustration of the advantageous shape of the tapered reflector, where the shape ensures that no light rays emitted by the OLED that are outside the escape cone for the tapered reflector material can directly hit the top surface of the tapered reflector, without first being reflected by the side walls of the tapered reflector.

FIG. 5A is a schematic diagram based on a micrograph that illustrates an example red-green-blue (RGB) pixel geometry of an OLED display for a mobile phone, and showing an array of tapered reflectors arranged over the OLED pixels;

FIG. 5B is a close-up cross-sectional view of a portion of the OLED display of FIG. 5A that shows the blue and green OLED pixels, which have different sizes;

FIG. 6A is a plot of the light extraction efficiency LE (%) versus the refractive index np of a central tapered reflector in an array of tapered reflectors;

FIG. 6B is a plot of the light output LL from a first diagonal tapered reflector relative to the central tapered reflector in the array of tapered reflectors versus the refractive index np of a central tapered reflector in an array of tapered reflectors;

FIG. 6C is a plot of the light output from a neighboring tapered reflector relative to the central tapered reflector in the array of tapered reflectors versus the refractive index np of a central tapered reflector in an array of tapered reflectors;

FIG. 6D is a plot of the coupling efficiency CE (%) versus the offset dX (mm) of the OLED relative to the bottom surface of the tapered reflector as measured using a large detector (diamonds) and a small detector (squares);

FIG. 7A is a plot of the calculated shear stress max in the glue layer as a function of the elastic modulus E_{g} (MPa) of the glue layer for a 60° C. temperature change;

FIG. 7B is a plot of the calculated shear stress max in the glue layer as a function of the elastic modulus Eₚ (MPa) of the tapered reflector material for the same 60° C. temperature change as FIG. 7A;

FIG. 8 is a plot of the light extraction efficiency LE (%) versus the refractive index nₛ of a material filling the spaces between tapered reflectors in an array of tapered reflectors;

FIGS. 9A and 9B are side views of a section of the OLED display that illustrate different configurations for the light extraction apparatus disclosed herein;

FIG. 10A is a schematic diagram of a generalized electronic device that includes the OLED display disclosed herein;

FIGS. 10B and 10C are examples of the generalized electronic device of FIG. 10A; and

FIGS. 11A and 11B illustrate an exemplary method for fabricating a flexible OLED display.

### DETAILED DESCRIPTION

Reference will now be made in detail to embodiments of the present disclosure, examples of which are illustrated in the accompanying drawings. Whenever possible, the same reference numerals will be used throughout the drawings to refer to the same or like parts. However, this disclosure may be embodied in many different forms and should not be construed as limited to the embodiments set forth herein.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom, vertical, horizontal—are made only with reference to the figures as drawn and are not intended to imply absolute orientation.

Unless otherwise expressly stated, it is in no way intended that any method set forth herein be construed as requiring that its steps be performed in a specific order, nor that with any apparatus, specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an,” and “the” include plural references unless the context clearly dictates otherwise. Thus, for example, reference to “a” component includes aspects having two or more such components, unless the context clearly indicates otherwise.

Cartesian coordinates are used in the Figures for the sake of reference and ease of discussion and are not intended to be limiting as to orientation or direction.

The term “light extraction” in connection with an OLED refers to apparatus and method for increasing the amount of light emitted from the OLED using features that do not reside within the actual OLED layered structure.

The unit abbreviation MPa used herein stands for “megapascal”.

The refractive index n_{O} of the OLED is an effective refractive index that includes contributions from the various layers that make up the OLED structure and in an example is in the range from about 1.6 to 1.85, while in another example is in the range from about 1.7 to 1.8, and in another example is in the range from about 1.76 to 1.78.

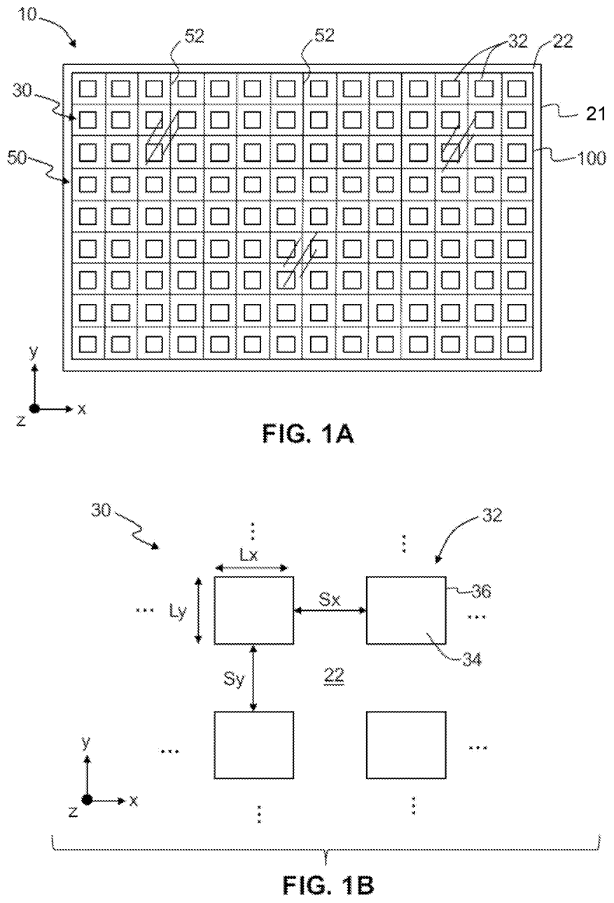

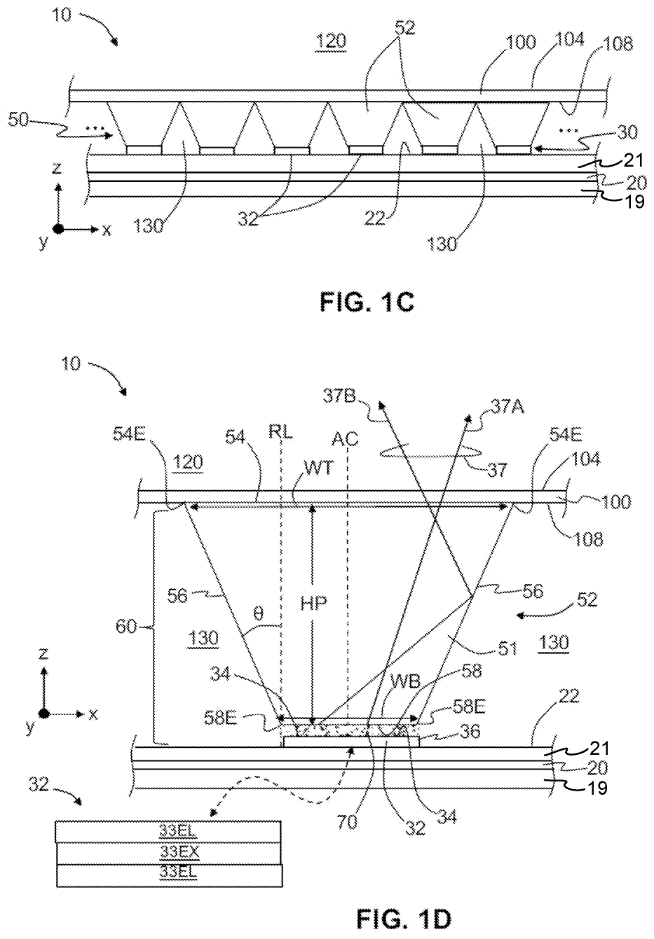

Referring now to FIG. 1A, a top-down view of an exemplary top-emitting OLED display (“OLED display”) 10 is depicted. FIG. 1B is a close-up top-down view of a section of OLED display 10 while FIG. 1C is a close-up x-z cross-sectional view of a section of the OLED display. FIG. 1D is an even more close-up view of the section of OLED display 10 shown in FIG. 1C.

With reference to FIGS. 1A through 1D, the OLED display 10 includes a flexible substrate 19, a buffer layer 20, and a thin-film-transistor (TFT) layer 21 having an upper surface 22. In certain exemplary embodiments, flexible substrate 19 may be made of polyimide, polyethylene terephthalate (PET), polycarbonate, or another suitable material. The OLED display 10 also includes an array 30 of top-emitting OLEDs 32 that resides on upper surface 22 of TFT layer 21. Each OLED 32 is electrically coupled to a transistor of TFT layer 21. Each OLED 32 has an upper or top surface 34 and sides 36. As shown in the close-up inset of FIG. 1D, OLED 32 includes a light-emitting layer 33EX between electrode layers 33EL. In an example, the upper electrode layer 33EL is a substantially transparent anode while the lower electrode layer is a metal cathode. Other layers, such as electron and hole injection and transport layers, and a substrate layer, are not shown for ease of illustration.

The OLEDs 32 have a length Lx in the x-direction and a length Ly in the y-direction. In one embodiment, Lx equals Ly. The OLEDs 32 in OLED array 30 are spaced apart from each other in the x-direction and the y-direction by side-to-side spacings Sx and Sy, as best seen in the close-up inset of FIG. 1B. In one embodiment, Sx equals Sy. The OLEDs 32 emit light 37 from top surface 34. Two light rays 37A and 37B are shown and discussed below. In one embodiment, the OLEDs 32 are all the same size and are equally spaced apart. In other embodiments, the OLEDs do not all have the same dimensions Lx, Ly and the spacings Sx, Sy are not all the same.

The OLED display 30 further includes an array 50 of tapered reflectors 52 operably disposed respective to OLEDs 32, i.e., with one tapered reflector aligned and operably disposed (i.e., optically coupled or optically interfaced) with one OLED. Each tapered reflector 52 includes a body 51, a top surface 54, at least one side surface 56, and a bottom surface 58. The top surface 54 includes at least one outer edge 54E, and bottom surface 58 includes at least one outer edge 58E. The tapered reflector body 51 is made of a material having a refractive index np.

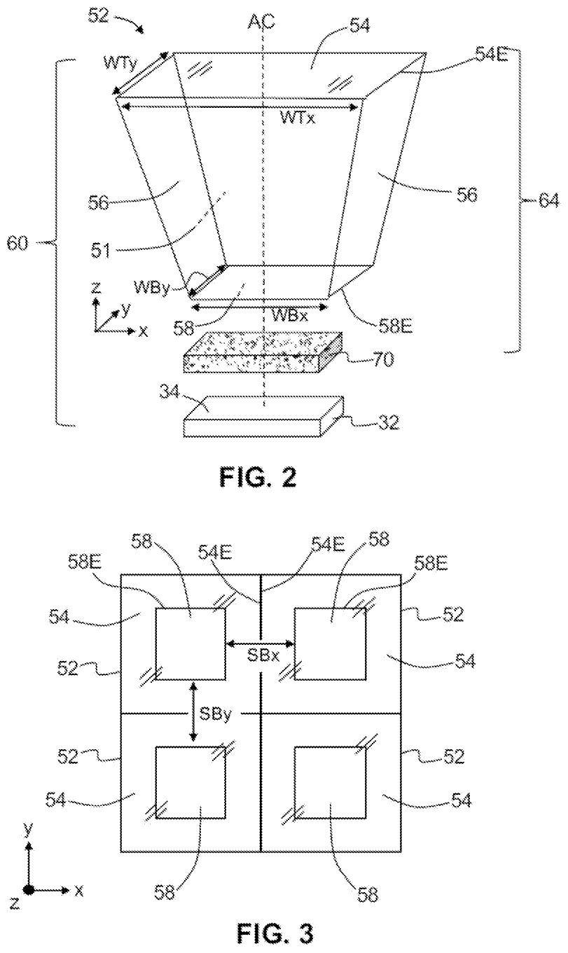

FIG. 2 is an elevated exploded view of an example light-emitting apparatus 60 formed by a tapered reflector 52, an index-matching material 70, and an OLED 32. The top surface 54 of tapered reflector 52 is larger (i.e., has a greater surface area) than the bottom surface 58, i.e., the top surface is the “base” of the tapered reflector. In one embodiment, the top and bottom surfaces 54 and 58 are rectangular (e.g., square) so that there are a total of four side surfaces 56. In an example where tapered reflector 52 is rotationally symmetric, it can be said to have one side surface 56. Side surfaces 56 can each be a single planar surface or made of multiple segmented planar surfaces, or be a continuously curved surface.

Thus, in one example, tapered reflector 52 has the form of a truncated pyramid comprising a trapezoidal cross-section, also called an incomplete or truncated rectangular-based pyramid. Other shapes for tapered reflector 52 can also be effectively employed, as discussed below. The tapered reflector 52 has a central axis AC that runs in the z-direction. In the example where top surface 54 and bottom surface 58 have a square shape, the top surface has a width dimension WT and the bottom surface has a width dimension WB. More generally, the top surface 54 has (x, y) width dimensions WTx and WTy and bottom surface 58 has (x, y) width dimensions WBx and WBy (FIG. 2). The tapered reflector 52 also has a height HP defined as the axial distance between top and bottom surfaces 54 and 58 (FIG. 1D).

As best seen in FIG. 1D, the bottom surface 58 of tapered reflector 52 is arranged on OLED 32 with bottom surface 58 residing adjacent the top surface 34 of the OLED. The index-matching material 70 has a refractive index n_{IM} and is used to interface tapered reflector 52 to OLED 32. The tapered reflector refractive index np is preferably, for example, as close as possible to the OLED refractive index n_{O}. In one embodiment, the difference between nₚ and n_{O} is no more than about 0.3, more preferably no more than about 0.2, more preferably no more than about 0.1, and most preferably no more than about 0.01. In another embodiment, the index-matching material refractive index n_{IM} is no lower than the tapered reflector refractive index np, and preferably has a value between nₚ and n_{O}. In an example, the tapered reflector refractive index np is between about 1.6 and 1.8.

In one embodiment, the index-matching material 70 has an adhesive property and serves to attach tapered reflector 52 to the OLED 32. Index-matching material 70 comprises, for example, a glue, an adhesive, a bonding agent, or the like. As noted above, the combination of OLED 32, tapered reflector 52 and index-matching material 70 define a light-emitting apparatus 60. The tapered reflector 52 and index-matching material 70 define a light extraction apparatus 64. In certain exemplary embodiments, index-matching material 70 can be omitted by arranging bottom surface 58 of tapered reflector 52 to be in intimate contact with the top surface 34 of OLED 32, e.g., in optical contact.

The OLED display 10 also includes a flexible barrier film 100 that has an upper surface 104 and a lower surface 108 (FIG. 1C). In certain exemplary embodiments, flexible barrier film 100 is a multi-layer film, such as a Vitex film. The multi-layer film may consist of alternating layers of organic and inorganic materials. A principle of operation of the multi-layer film is that microscopic pinholes in very thin inorganic layers are decoupled by organic spacer layers. Together, the multiple layers can provide, for example, the best hermeticity in the smallest possible total thickness. The specific materials used to make flexible barrier film 100 may vary. For example, the inorganic layers may be oxides such as SiO₂ and Al₂O₃, nitrides such as SiNx, oxynitrides such as SiOxNy, or carbon nitrides such as SiCNx. The organic layers may be, for example, acrylates, epoxies, polycarbonate, polystyrene, cyclic olefins, polyethylene terephthalate (PET), polyethylene naphthalate (PEN), or other suitable materials. In certain exemplary embodiments, the same material may be used for all the layers, such as hexamethyldisiloxane (HMDSO), which possesses either inorganic or organic properties depending on process tuning. The entire barrier film can then be made using the same plasma-enhanced chemical-vapor deposition (PECVD) process. Other types of barrier films may also be used based, for example, on a single layer of a hybrid organic-inorganic composite material.

The top surfaces 54 of tapered reflectors 52 reside immediately adjacent and in contact with the lower surface 108 of flexible barrier film 100. In an example best illustrated in FIG. 1C, the top surfaces 54 of tapered reflectors 52 tile the lower surface 108 of flexible barrier film 100 without any substantial space in between top edges 54E.

In certain exemplary embodiments, tapered reflectors 52 are formed as a unitary, monolithic structure made of a single material. This can be accomplished using a molding process, imprinting process (e.g., ultraviolet or thermal imprinting), or like process, such as a microreplication process using a resin-based material.

An external environment 120 exists immediately adjacent upper surface 104 of flexible barrier film 100. The external environment 120 is typically air, although it can be another environment in which one might use a display, such as vacuum, inert gas, etc. FIG. 3 is similar to FIGS. 1B and 1s a top-down view that shows four OLEDs 32 and their corresponding four tapered reflectors 52 with top surfaces 54. Note that outer edges 54E of the top surfaces 54 of adjacent tapered reflectors 52 reside immediately adjacent one another. In certain exemplary embodiments, the outer edges 54E are in contact with each other. The bottom surfaces 58 are shown as having (x, y) edge spacings between adjacent bottom-surface edges 58E of SBx and SBy, respectively. In certain exemplary embodiments, the bottom surface 58 is no more than 90% of the size of the top surface 34 of OLED 32.

With reference again to FIG. 1C, the array of tapered reflectors 52 define confined spaces 130 between adjacent tapered reflectors, the upper surface 22 of TFT layer 21, and the lower surface 108 of flexible barrier film 100. In certain exemplary embodiments, spaces 130 are filled with a medium such as air, while in other embodiments, the spaces are filled with a medium in the form of a dielectric material. The filling of spaces 130 with a given medium of refractive index n_{S} is discussed in greater detail below.

The tapered reflectors 52 are typically made of a material that has a relatively high refractive index, i.e., preferably as high as that of the OLED light-emissive layer 33EL. The tapered reflectors 52 are operably arranged upon corresponding OLEDs 32 in an inverted configuration using the aforementioned index-matching material 70. Each OLED 32 can be considered a pixel in OLED array 30, and each combination of OLED 32, index-matching material 70, and truncated pyramid 52 is a light-emitting apparatus 60, with the combination of light-emitting apparatus defining an array of light-emitting apparatus for OLED display 10.

Because of the relatively high refractive index np of the tapered reflectors 52 and the refractive index n_{IM} of index-matching material 70, light rays 37 generated in the OLED light-emissive layer 33EL of OLED 32 can escape from OLED top surface 34 either directly or upon being reflected by lower electrode 33EL without being trapped by TIR (FIG. 1D). After propagating through tapered reflector 52 directly to the top surface 54 (light ray 37A) or after being reflected and redirected by at least one side surface 56 (light ray 37B), the light escapes into flexible barrier film 100 and passes therethrough to external environment 120.

In certain exemplary embodiments, side surfaces 56 have a slope defined by a slope angle θ relative to the vertical, e.g., relative to a vertical reference line RL that runs parallel to central axis AC, as shown. If the slope of sides 56 is not too steep (i.e., if the slope angle θ is sufficiently large), the TIR condition will be met for any point of origin of the light rays 37 emanating from OLED top surface 34 and no light rays will be lost by passing through sides 56 and into the spaces 130 immediately adjacent the sides of tapered reflector 52.

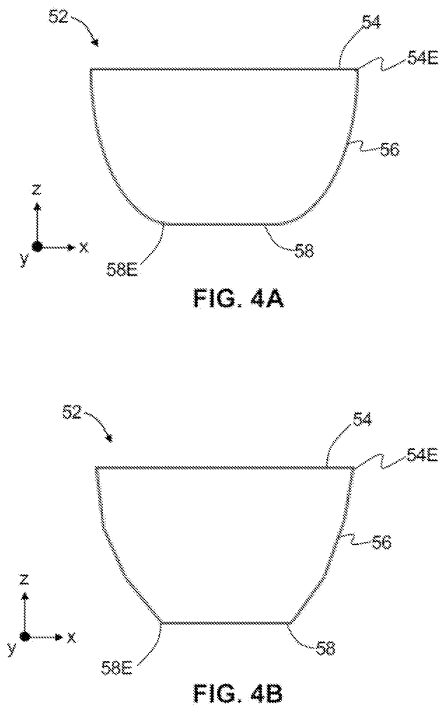

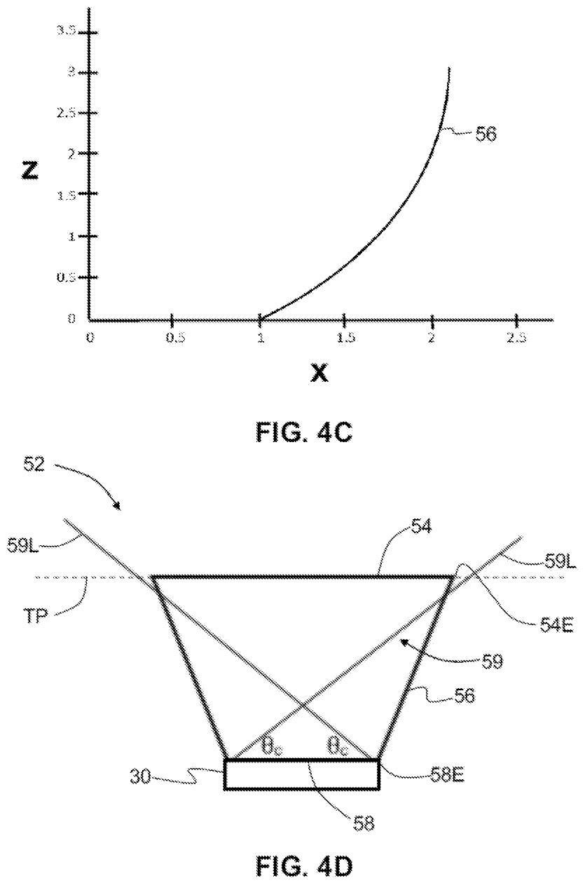

Moreover, if the height HP of tapered reflector 52 is sufficiently large, all of the light rays 37 incident upon the top surface 54 will be within a TIR escape cone 59 (FIG. 4D) defined by the refractive index np of tapered reflector 52 and the refractive index n_{E} of the flexible barrier film 100 and thus escape into the flexible barrier film 100. In addition, light rays 37 will also be within the TIR escape cone defined by the refractive index n_{E} of the material of flexible barrier film 100 and the refractive index nₑ of the external environment that resides immediately adjacent the upper surface 104 of the flexible barrier film 100.

Thus, neglecting light absorption of the otherwise transparent upper electrode 33EL in the OLED structure of OLED 32, 100% of light 37 generated by the OLED can in principle be communicated into the external environment 120 that resides above flexible barrier film 100. In essence, the index-matched material that makes up body 51 of tapered reflector 52 allows for the tapered reflector 52 to act as a perfect (or near-perfect) internal light extractor while the reflective properties of sides 56 allow for the tapered reflector to be a perfect (or near-perfect) external light extractor.

Explanation of TIR Conditions

At the boundary of any two dissimilar transparent materials such as air and glass having refractive indices n1 and n2, respectively, light rays incident upon the boundary from the direction of the higher-index material will experience 100% reflection at the boundary and will not be able to exit into a lower index material if they are incident at the boundary at an angle to the surface normal which is higher than a critical angle θ_{c}. The critical angle is defined by sin(e)=n1/n2.

All light rays that are able to escape the higher-index material and not be subjected to TIR therein will lay within a cone having a cone angle of 2θ_{c}. This cone is referred to as the escape cone and discussed below in connection with FIG. 4D.

It can be shown that for any sequence of layers with arbitrary refractive indices, the critical angle θ_{c} and the escape cone 59 are defined by the refractive index of the layer where the light ray originates, and the refractive index of the layer or medium into which it escapes. Thus, an anti-reflective coating cannot be used to modify the TIR condition and cannot be used to aid light extraction by overcoming TIR conditions.

For a point source with isotropic emission into a hemisphere and the same intensity for any angle, the amount of light able to escape the source material is equal to the ratio of the solid angle of the escape cone 59 is given by 2π(1−cos(θ_{c})) and the full solid angle of the hemisphere (2π) is equal to 1−cos(θ_{c}). Taking an example of an OLED material with a refractive index n2=1.76 and air with refractive index n1=1.0, the critical angle is θ_{c}=arcsin(1/1.76)=34.62°.

The amount of light that will exit into the air for any sequence of different material layers on top of the OLED material (i.e., the light output as compared to the light input) is equal to 1−cos(34.62°)=17.7%. This is referred to as the external light extraction efficiency LE. This result assumes the OLED is an isotropic emitter, but the estimate of the light extraction efficiency based on this assumption is very close to the actual result obtained with more rigorous analysis and what is observed in practice.

Tapered Reflector Shape Considerations

FIG. 4A is a side view of an exemplary tapered reflector 52 that includes at least one curved side surface 56. FIG. 4B is a side view of an embodiment of another tapered reflector 52 that includes at least one segmented planar side surface 56. In certain exemplary embodiments, one or more side surfaces 56 can be defined by a single curved surface, e.g., cylindrical, parabolic, hyperbolic, or any other shape besides planar, as long as tapered reflector 52 is wider at top surface 54 than at bottom surface 58. In one embodiment, tapered reflector 52 is rotationally symmetric and so includes a single side 56.

Although not strictly required, the performance of light-emitting apparatus 60 is optimized if at any point on side surface 56 of tapered reflector 52 the TIR condition is observed for any possible point of origin of light 37 within the OLED emission layer 33EL of OLED 32. FIG. 4C is a plot of the z coordinate vs. x coordinate (relative units) for an example complex surface shape for side surface 56 calculated using a simple numerical model. The z and x axes represent normalized lengths in the respective directions. The OLED 32 is assumed to extend in the x-direction from [−1, 0] to [1, 0], and there is another side 56 that starts at [−1, 0] location but that is not shown in the plot of FIG. 4C. The shape of side 56 was calculated such that rays originating at [−1, 0] are always incident on the surface exactly at 45° to a surface normal. Any other ray originating at z=0 and x between −1 and 1 will have a higher incidence angle on side 56 than the ray originating at [−1, 0].

Performance of light-emitting apparatus 60 can be further improved if the height HP of tapered reflector 52 is such that all of the light rays 37 emitted by OLED 32 exiting directly into the flexible barrier film 100 are within the escape cone 59, as illustrated in the schematic diagram of FIG. 4D. FIG. 4D includes a plane TP defined by the top surface 54 of tapered reflector 52. The condition is met when top surface 54 of tapered reflector 52 is entirely within (i.e., not intersected by) the lines 59L that define the limits of the escape cone 59. The escape cone lines 59L originate at the edges 58E of bottom surface 58 and intersect plane TP at the critical angle θ_{c} with respect to top surface 54, where the value of θ_{c} is defined by the refractive index of the tapered reflector material nₚ and air nₐ as sin(θ_{c})=nₐ/nₚ.

In a general case, there exists an optimum height HP of the tapered reflector 52 that depends on the geometry (size of and spacing between) OLEDs 32 and the refractive index nₚ of tapered reflectors 52. If the height HP is too small, all light rays 37 emitted from the OLEDs 32 will undergo TIR at the side surfaces 56 of the tapered reflector 52, but some rays will go directly to the top surface 54 and be incident thereon at an angle larger than the critical angle and therefore will be trapped at the first boundary with air in the display. If the height HP is too large, all light rays 37 going directly to the top surface 54 will be within the escape cone 59, but some light rays falling on the side surfaces 56 will be within the escape cone for the side surfaces and thus exit the side surfaces. In certain exemplary embodiments, the optimum height HP of the tapered reflectors HP is typically between (0.5)WB and 2WT, more typically between WB and WT. Also in one embodiment, the local slope of the side walls 56 can be between about 2° and 50°, or even between about 10° and 45°.

### Tapered Reflector Array

As noted above, the plurality of tapered reflectors 52 define a tapered reflector array 50. The bottom surfaces 58 of the tapered reflectors 52 are respectively aligned with and optically coupled to top surfaces 34 of OLEDs 32. Since the top surfaces 54 of tapered reflectors 52 are larger than the bottom surfaces 58, in one example (see FIG. 1C) the top surfaces are sized to cover substantially the entire lower surface 108 of flexible barrier film 100, or as close as the specific manufacturing technique employed allows.

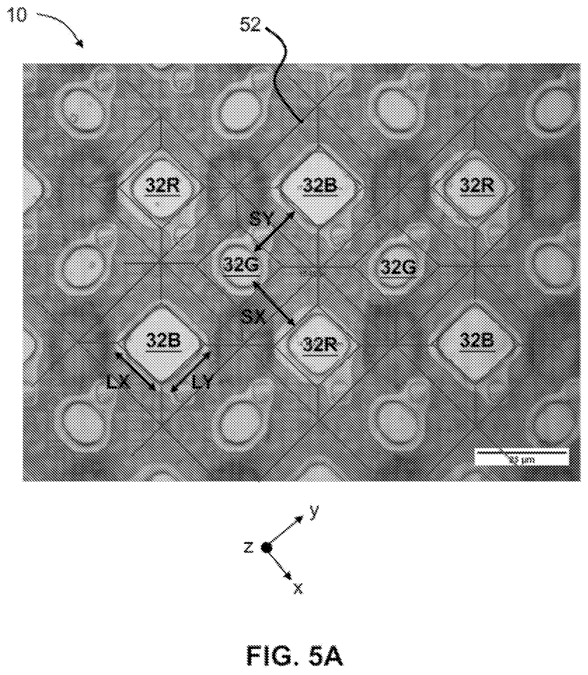

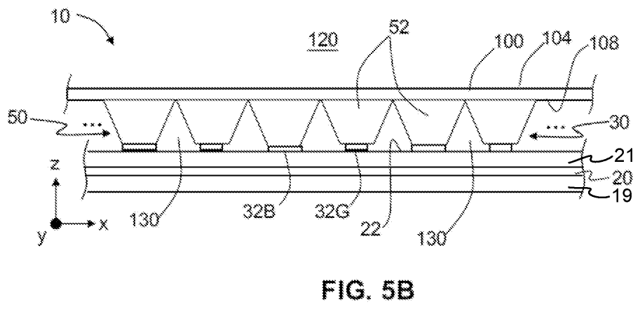

FIG. 5A is a schematic diagram based on a micrograph that illustrates an example red-green-blue (RGB) pixel geometry of an OLED display 10 for a mobile phone. FIG. 5B is a cross-sectional view of a portion of the OLED display 10 that shows green OLEDs 32G and blue OLEDs 32B. The pixels are defined by OLEDs 32 arranged in a diamond pattern, so that the OLEDs are also referred to as OLED pixels. The x- and y-axes can be considered as rotated clockwise by 45°, as shown in FIG. 5A.

The OLEDs 32 emit colored light and are denoted 32R, 32G, and 32B for red, green, and blue light emission, respectively. The solid lines depict the contours of the eight tapered reflectors 52 associated with the eight colored OLEDs 32 shown. The top surfaces 54 of tapered reflectors 52 are touching each other while the bottom surfaces 58 fully cover their respective OLEDs 32R, 32G, and 32B. Since green OLEDs 32G are smaller than the blue OLEDs 32B and yet a perfectly periodic array is preferable, the bottom surfaces 58 of the respective tapered reflectors 52 are sized to the blue OLEDs and are slightly oversized with respect to the green OLEDs.

In another embodiment, the configuration of array 50 of tapered reflectors 52 is configured to match the configuration of the array 30 of OLEDs. Thus, the tapered reflectors 52 may not all have the same dimensions WBx, WBy and may not all have the same bottom-edge spacings SBx, SBy.

The example OLED display 10 can be thought of as having a solid material layer residing immediately above OLEDs 32 with a thickness equal to the height HP of tapered reflectors 52 and with a rectangular grid of intersecting V-groove spaces 130 cut into the solid material layer. Such a structure can be microreplicated in a layer of suitable resin or a photocurable or thermally curable material, with a master replication tool configured to define a rectangular grid of triangular cross-section ridges. Such a tool, for example, can be manufactured by first diamond machining the pattern that looks exactly like the tapered reflector array, and then making a master by replicating an inverse pattern. The master can be metalized for durability.

As shown in FIG. 5A and FIG. 5B, in an example, the spacing Sx and Sy between the colored OLEDs 32R, 32G, and 32B is approximately equal to the size Lx, Ly of the largest OLED (i.e., the blue OLED 32B). If the tapered reflector top surface 54 is twice as large as the bottom surface 58, and the height HP of the tapered reflector is 1.5 times as tall as the bottom surface is wide, and the side walls are flat, then the slope angle θ of side surface 56 is arctan(⅓)=18.4°. Manufacturing tapered reflector 52 or an array 50 of tapered reflector 52 having this slope angle is within the capability of diamond machining technology.

If the bottoms of the V-grooves are more rounded, then for the same slope angle θ, the height HP of tapered reflector 52 can be smaller than 1.5 times the size (dimension) of the bottom surface 58. For a different configuration of OLED display 10, or a different technique for making the replication masters, different restrictions on the geometry of the tapered reflectors may apply.

As explained above, to form a periodic array 50 of tapered reflectors 52, the replication tool or mold is a negative replica of the structure, which might be considered to be an array of truncated depressions or “bowls”. When using such a tool for forming tapered reflector array 50, it may be preferred to avoid trapping air in the bowls when the tool is pressed into a layer of liquid or moldable replication material. One technique to avoid such air trapping is to manufacture a replication tool or mold as an array of complete and not truncated pyramidal bowls. In this case, the height of the tapered reflectors can be controlled by the thickness of the replication material layer. The tool is pressed in the replication material until in comes in contact with flexible barrier film 100. Air pockets will be left above each of the replicated tapered reflectors on purpose. Care can be taken to avoid rounding of the tapered reflector tops by surface tension.

### Light Extraction Efficiency

To estimate the light extraction efficiency of the tapered reflectors 52 in OLED display 10, ray tracing was performed using standard optical design software for a modeled OLED display. A 5×5 array 50 of tapered reflectors 52 was considered. Each tapered reflector 52 had a bottom surface size of 2×2 units, a top surface size of 4×4 units and a height HP of 3 units. These dimensionless units are sometimes called “lens units” and are used when the modeling results scale linearly. The tapered reflectors 52 were sandwiched between two pieces of glass each with a refractive index of 1.51. Immediately under the bottom surface 58 of each tapered reflector 52 was placed a very thin layer of a material with a refractive index of 1.76. This thin layer serves the role of the OLED and so is referred to as the OLED layer. The uppermost piece of glass served as the flexible barrier film 100 of the OLED display 10.

The bottom surface of the OLED layer was set to be perfectly reflective to represent a reflective bottom electrode 33EL. A source of light was placed within the OLED layer and under the central tapered reflector 52 in the 5×5 array. The light source was isotropic (i.e., uniform intensity versus angle) and had the same transverse dimensions as the bottom surface 58 of tapered reflector 52. The light output from the top (flexible barrier film) was then calculated. Modeling of the light emission from the modeled OLED display was carried out with and without the tapered reflectors 52 to determine the light emission efficiency LE. The light output was determined by select placement of virtual detectors. Without the array 50 of tapered reflectors 52, the light output was about 16.8% of the source output, which is very close to the 17.7% value calculated above based on a simplified calculation of the size of the escape cone.

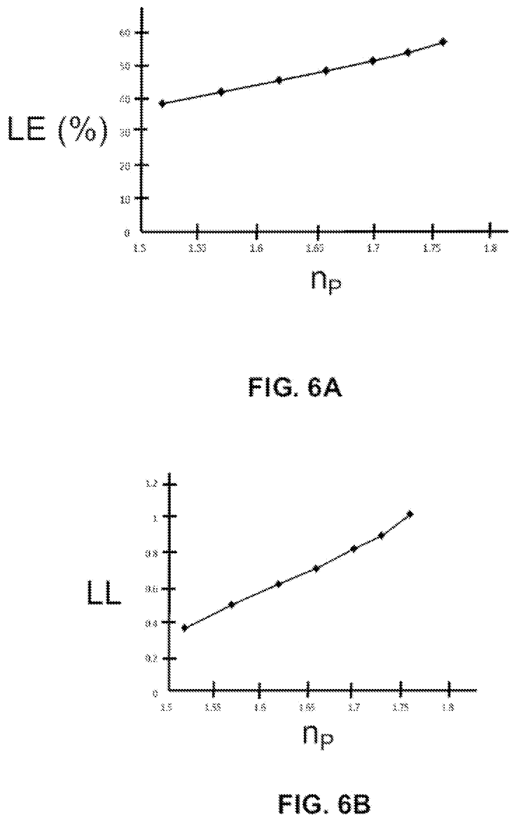

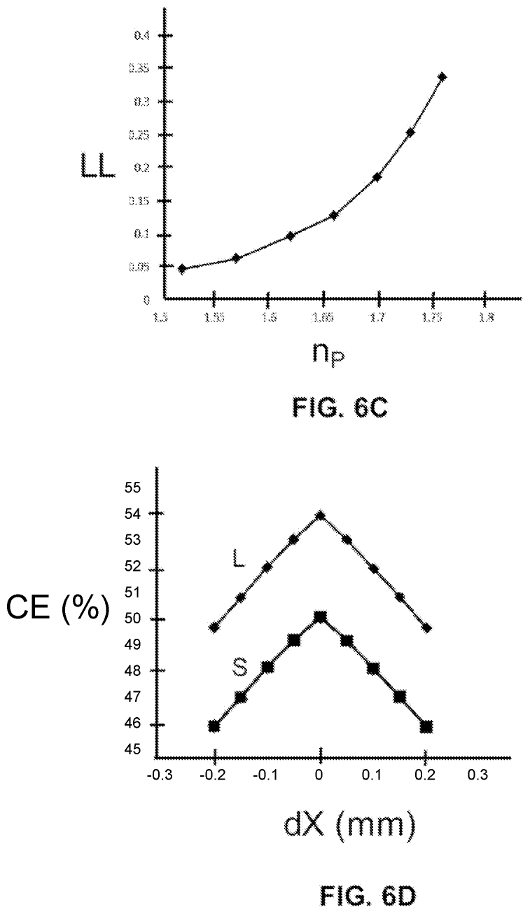

The light extraction efficiency LE (%) with tapered reflectors 52 are shown in the plots of FIGS. 6A through 6C. The horizontal axis is the refractive index np of the tapered reflectors. In FIG. 6A, the vertical axis is the light extraction efficiency LE (%). It is noted that there is some light spillover to the adjacent tapered reflectors 52. The power out of each tapered reflector 52 in tapered reflector array 50 is easily estimated in the model by placing a small rectangular (virtual) detector at top surface 54 of the given tapered reflector. For simplicity, the light extraction efficiency LE (%) is defined here as the power out of the central tapered reflector divided by the total power emitted by the light source.

As can be seen from FIG. 6A, light extraction efficiency LE reaches 57.2%, or 3.2 times (220%) higher than 17.7%, if the refractive index np of the tapered reflector matches that of the OLED layer, namely 1.76. However, even for n_{P}=1.62, the light extraction efficiency LE is improved by 2.57× (i.e., 157%), that is, from 17.7% to 45.8%. This does not take into account the “focusing” effect due to the tapered shape of tapered reflector 52, so the gain in brightness in the normal direction might be even slightly higher, depending on the details of the OLED structure and the precise shape and height of the tapered reflectors. In various embodiments, the light extraction efficiency LE is greater than about 15% or greater than about 20% or greater than about 25% or greater than about 30% or greater than about 40% or greater than about 50%, depending on the various parameters and configuration of the components of light-emitting apparatus 60.

With reference again to FIGS. 5A and 5B, in case of the diamond arrangement for the OLED display 10, for the green OLEDs 32G, the nearest neighbor of the same color is under the next diagonal tapered reflector and for the blue and red OLEDs 32B and 32R, the nearest neighbor of the same color is under the second tapered reflector to any of the four sides. The light leakage LL, which is defined as the light output of side tapered reflectors divided by the light output of the central one, is plotted in FIG. 6B and in FIG. 6C, also as a function of the tapered reflector refractive index np. FIG. 6B is for the closest diagonal tapered reflector 52 while FIG. 6C is for the second neighboring tapered reflector to the right of the central tapered reflector. As is evident from FIG. 6B, the light leakage to the next tapered reflector associated with the same color OLED is about 0.6% for the green OLED 32G and 0.2% for blue and red OLEDs 32B and 32R, for the same tapered reflector material with n_{P}=of 1.62.

The modeling as described above was performed using principles of geometrical optics and so does not take into account other effects better described by wave optics. The geometric-optics model also does not take into account effects that are internal to OLED 32. Taking these other factors into account is expected to slightly increase the calculated light emission efficiency and affects internal light extraction, i.e., extracting light from within the OLED structure so that more exits the OLED top surface 34. The apparatus and methods disclosed herein are directed to light extraction, i.e., extracting light using structures that are external to OLED 32.

The improved light-emission apparatus and methods disclosed herein rely entirely on light reflection and not light scattering. Thus, the polarization of ambient light reflected by a reflective electrode 33EL is unchanged upon reflection, which means that the approach is perfectly compatible with the use of circular polarizers. Also, there is no haze in reflection and therefore no decrease of the display contrast ratio, which is a problem characteristic of almost all other approaches to improving light extraction using scattering techniques.

### Alignment Considerations

All of the light extraction efficiency values quoted above assumed perfect alignment between the OLED 32 source and bottom surface 58 of tapered reflector 52. The same type of modeling as used above was also used to estimate the sensitivity to misalignment between OLED 32 and tapered reflector 52. FIG. 6D plots the coupling efficiency CE versus an x-offset dX (mm) for the case where refractive index np of the tapered reflector is the same as that of OLED 32.

The results show that the output power (and therefore the coupling efficiency CE) scales linearly with offset dX, with an offset of 10% causing about an 8% drop in light output. The virtual detectors in the model were placed at the outer surface of the flexible barrier film (boundary with air). In FIG. 6D, the curve S is for a “small detector” and refers to a virtual detector the same size as the top of the tapered reflector. Likewise, the curve L is for a “large detector” and refers to a slightly larger virtual detector designed to capture all rays exiting the tapered reflector on top of the emitting OLED.

Modeling was also carried out for a 10×10 array 50 of tapered reflectors 52 to estimate a possible decrease in sharpness or contrast ratio of the OLED display 10 caused by the light leakage to neighboring tapered reflectors. The modeling indicated that such light leakage did not have a substantial impact on the contrast ratio.

### CTE Mismatch Considerations

In conventional OLED displays, the coefficient of thermal expansion (CTE) of the flexible barrier film is the same or very similar to that of the OLED substrate. However, the CTE of tapered reflectors 52 can be substantially different, especially in the case when the tapered reflectors are formed using a polymer or a hybrid (organic with inorganic filler) resin.

A simple estimate of the magnitude of mechanical stress that will be induced in light-emitting apparatus 60 as the environment temperature changes was performed using the approach described in the publication by W. T. Chen and C. W. Nelson, entitled “Thermal stress in bonded joints,” IBM Journal of Research and Development, Vol. 23, No. 2, pp. 179-188 (1979) (hereinafter, “the IBM publication”), which is incorporated herein by reference.

The light-emitting apparatus 60 of FIG. 1D was modeled as a three-layer system of a tapered reflector 52 made of a resin, an index-matching material 70 in the form of a glue layer, and an OLED 32 made of glass. The maximum shear stress τₘₐₓ in the glue layer 70 was calculated using the following equations from the IBM publication:

$${τ}_{max} = \frac{( {α}_{1} - {α}_{2} ) Δ TG tanh ( β l )}{β t}$$

$$β = {[ \frac{G}{t} ( \frac{1}{{E}_{1} {h}_{1}} + \frac{1}{{E}_{2} {h}_{2}} ) ]}^{\frac{1}{2}}$$

where G is the shear modulus of the glue layer, 1 is the maximum bond dimension from center to edge (half diagonal in case of a square sub-pixel and tapered reflector bottom), t is the thickness of the glue layer, α₁ and α₂ are the coefficients of thermal expansion of the bonded materials (i.e., for the resin of tapered reflector and for glass, in units of ppm/° C.), ΔT is the change in temperature (° C.), E₁ and E₂ are the Young's moduli and the h₁ and h₂ are the thickness of the bonded materials, i.e., the resin and glass, respectively. Note that h₁ is the same as the tapered reflector height HP.

The calculations assumed that the bottom surface 58 of tapered reflector 52 had dimensions of 16×16 μm, and also assuming that 1=11.3 μm and t=2 μm, the height of the tapered reflector HP=h₁=24 μm, and taking α₁−α₂=70 ppm/° C., ΔT=60° C., and a Poisson ratio of the glue of 0.33 (typical for epoxies).

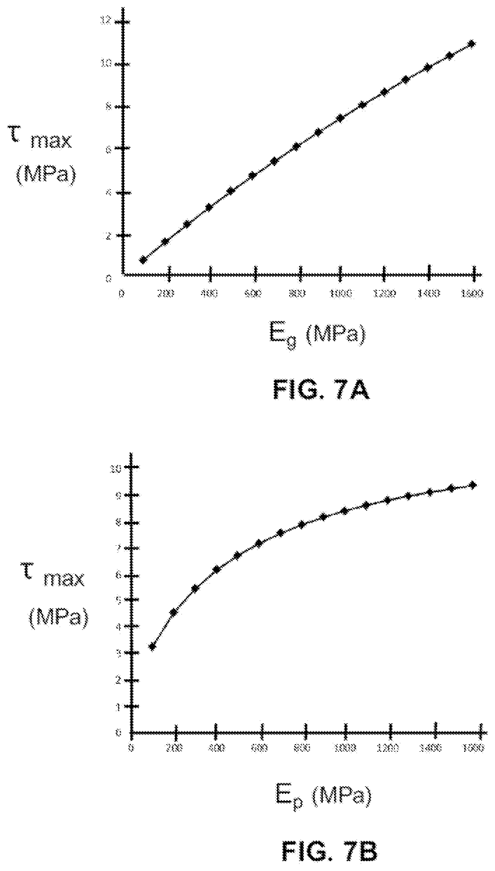

FIG. 7A is a plot of the calculated shear stress τₘₐₓ in the glue layer 70 as a function of the elastic modulus E_{g} (MPa) of the glue layer for a 60° C. temperature change, while FIG. 7B is a plot of the calculated shear stress τₘₐₓ in the glue layer 70 as a function of the elastic modulus Eₚ (MPa) of the resin material of the tapered reflector, for the same 60° C. temperature change. The shear modulus G values were calculated from elastic modulus Eₚ and the Poisson ratio v using G=Eₚ/(2(1+v)). The calculated values of the shear stress τₘₐₓ in the glue layer 70 range from 1 to 11 MPa. There are many commercially available glues having a shear strength higher than 11 MPa. In addition, a 60° C. temperature swing is quite extreme, consider that if the zero stress point is at room temperature of 20° C., this would mean taking the device to either −40° C. or 80° C.

It is generally considered beneficial to minimize possible temperature induced stress because temperature cycling can cause a gradual failure of the device. The results shown in FIGS. 7A and 7B suggest that this can be achieved by lowering the elastic modulus of the material used to form the truncated pyramids and/or by using a softer glue (i.e., one with a lower elastic modulus).

### Resin Tapered Reflectors

As noted above, in one embodiment the array 50 of tapered reflectors 52 can be formed using a resin since resins are amenable to molding processes and like mass-replication techniques. When forming the array 50 using a resin, it is preferred that edges of flexible barrier film 100 be free of resin so that it can be coated by a frit for edge sealing. In addition, it is preferred that the resin be able to survive a 150° C. processing temperature typical of making touch sensors. Also, it is preferred that the resin exhibit no or extremely low outgassing within the operating temperature range, at least of the type most detrimental for OLED materials, namely oxygen and water.

### Material for the Spaces Between the Tapered Reflectors

As noted above, the array 50 of tapered reflectors 52, the OLEDs 32 and flexible barrier film 100 define confined spaces 130 filled with a medium having a refractive index n_{S}. In certain exemplary embodiments, the confined spaces 130 are filled with air, which has a refractive index of n_{S}=nₐ=1. In other embodiments, spaces 130 can be filled with a solid material. It is generally preferred that the medium within spaces 130 has as low a refractive index as possible so that escape cone 59 stays as large as possible.

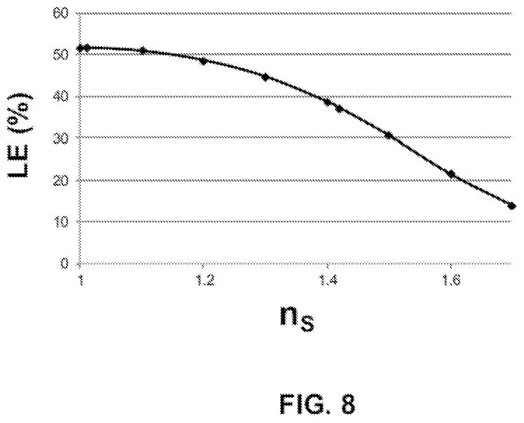

FIG. 8 is a plot of the light extraction efficiency LE (%) versus the index of refraction n_{S} of the material that fills spaces 130, assuming a refractive index n_{P}=1.7 for tapered reflector 52. The plot shows a greater than 2× (100%) improvement in light extraction efficiency (as compared to not using tapered reflector 52) even when the index n_{S} of the filler material for spaces 130 is as high as 1.42, which is a typical value for silicone adhesives.

To achieve the best possible light extraction benefit, it is preferable that the index n_{S} of the filler material be 1.2 or smaller. An example of a material with such a low refractive index is aerogel, which is a porous organic or inorganic matrix filled with air or another suitable dry and oxygen-free gas. A silica-based aerogel can also serve an additional role of absorbing any residual water contamination, increasing the lifetime of the OLED materials. If the material making up the body 51 of tapered reflector 52 has a refractive index np of 1.7 and the refractive index of aerogel is 1.2, then the critical angle θ_{c} will be about 45°, which is an acceptable critical angle.

### Tapered Reflector Modifications

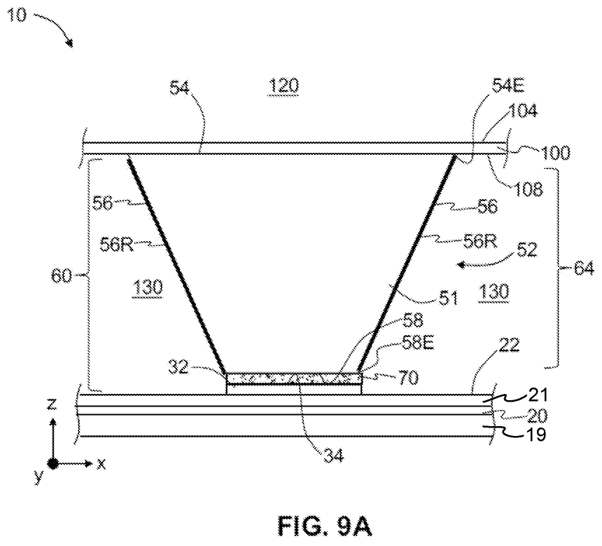

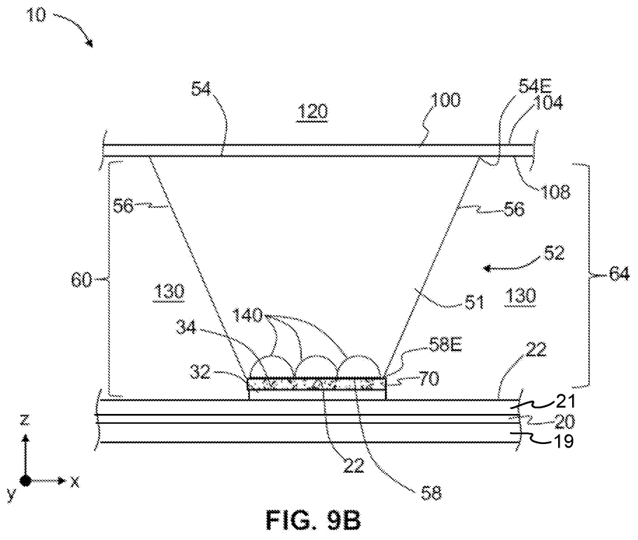

The tapered reflectors 52 can be modified in a number of ways to enhance the overall light extraction efficiency. For example, with reference to FIG. 9A, in one embodiment side surfaces 56 can include a reflective coating 56R. This configuration allows for essentially any transparent material to fill spaces 130 since the tapered reflectors 52 no longer operate using TIR.

Another modification is illustrated in the side view of FIG. 9B, which shows microlenses 140 formed on the bottom surface 58 of the tapered reflector 52 and that extend into the body 51 of the tapered reflector. The microlenses 140 have a refractive index n_{M} that is higher than the refractive index np of the body of the tapered reflector 52. The structure shown in FIG. 9B can be created by forming tapered reflector 52 with recesses (e.g., hemispherical, aspherical, etc.) at bottom surface 58 and then filling the recesses with a high-refractive-index material.

### Electronic Devices Utilizing the Flexible OLED Display

The flexible OLED displays disclosed herein can be used for a variety of applications including, for example, in consumer or commercial electronic devices that utilize a display. Example electronic devices include computer monitors, automated teller machines (ATMs), and portable electronic devices including, for example, mobile telephones, personal media players, and tablet/laptop computers. Other electronic devices include automotive displays, appliance displays, machinery displays, etc. In various embodiments, the electronic devices can include consumer electronic devices such as smartphones, tablet/laptop computers, personal computers, computer displays, ultrabooks, televisions, and cameras.

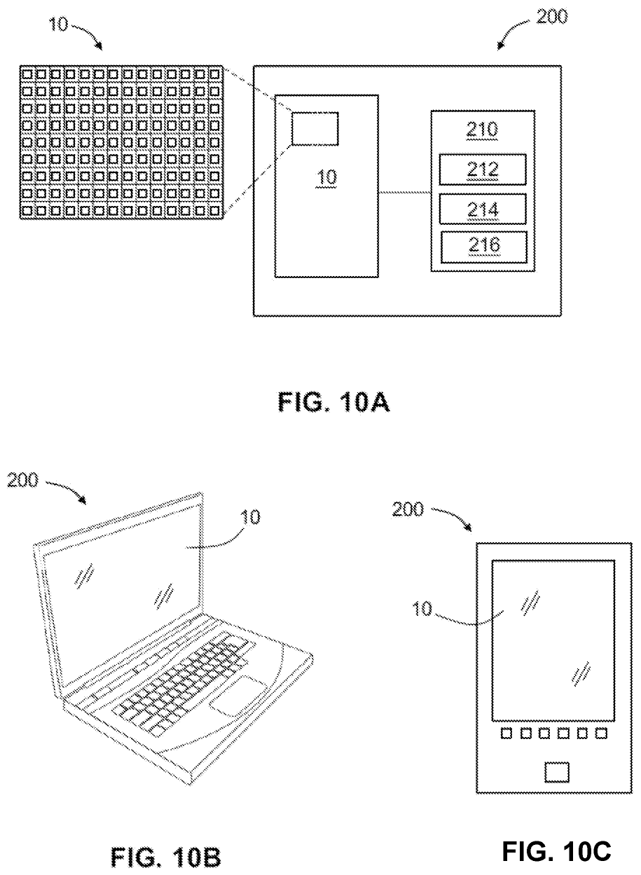

FIG. 10A is a schematic diagram of a generalized electronic device 200 that includes OLED display 10 as disclosed herein. The generalized electronic device 200 also includes control electronics 210 electrically connected to OLED display 10. The control electronics 210 can include a memory 212, a processor 214, and a chipset 216. The control electronics 210 can also include other known components that are not shown for ease of illustration.

FIG. 10B is an elevated view of an example electronic device 200 in the form of a laptop computer. FIG. 10C is a front-on view of an example electronic device 200 in the form of a smart phone.

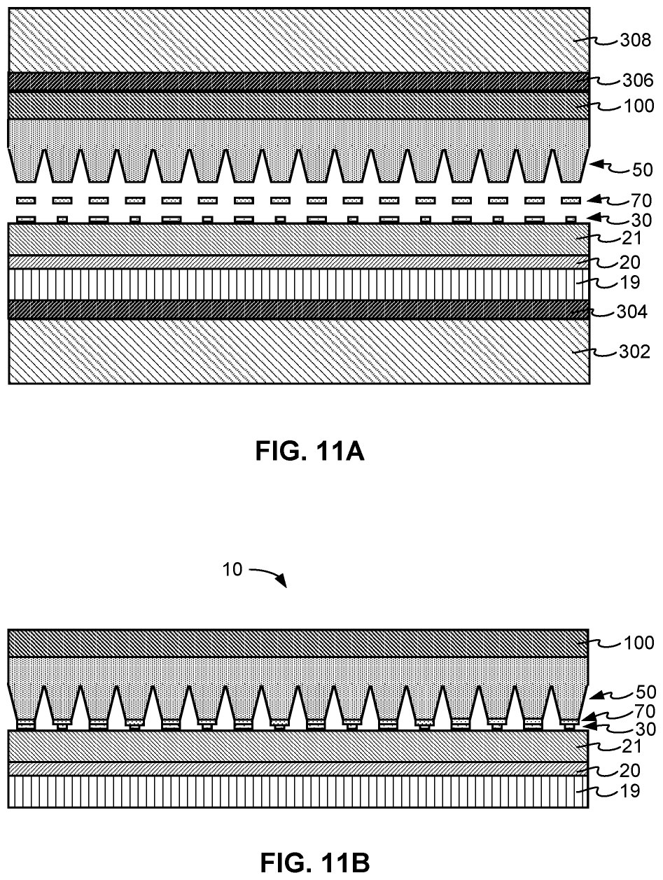

FIGS. 11A and 11B illustrate an exemplary method for fabricating a flexible OLED display. As shown in the lower portion of FIG. 11A, a first release layer 304 (e.g., an inorganic material or polymer) is applied on a first glass substrate 302. A flexible substrate 19 is applied on the first release layer 304. A buffer layer 20 may be applied on flexible substrate 19. Amorphous silicon is applied on buffer layer 20 for the fabrication of an active matrix of thin film transistors via, for example, a low temperature poly-silicon (LTPS-TFT) process to form TFT layer 21. An array 30 of OLEDs is formed on the TFT layer 21 such that each OLED is electrically coupled to a transistor of TFT layer 21.

As shown in the upper portion FIG. 11A, a second release layer 306 (e.g., an inorganic material or polymer) is applied on a second glass substrate 308. A flexible barrier film 100 is applied on the second release layer 306. An array 50 of tapered reflectors is formed on the flexible barrier film 100. Since the array 50 of tapered reflectors is formed on a rigid glass substrate 308, and the array 30 of OLEDs is formed on a rigid glass substrate 302, the fabrication accuracy required for pixel to pixel matching between the OLED pixels and individual truncated pyramids in the array becomes possible. The second glass substrate 308, the second release layer 306, the flexible barrier film 100, and the array 50 of tapered reflectors is applied to the array 30 of OLEDs such that the bottom surface of each tapered reflector of the array of tapered reflectors is coupled to an OLED of the array of OLEDs. An index-matching layer 70, such as an optically clear adhesive, may be applied between each OLED of the array of OLEDs and the bottom surface of each tapered reflector of the array of tapered reflectors.

FIG. 11B illustrates a flexible OLED display 10 after releasing the first release layer 304 to separate the first glass substrate 302 from the flexible substrate 19 and releasing the second release layer 306 to separate the second glass substrate 308 from the flexible barrier film 100. In certain exemplary embodiments, the first release layer 304 and the second release layer 306 are released by irradiating the first release layer 304 and the second release layer 306 with a laser. In this case, first release layer 304 and second release layer 306 release a significant amount of hydrogen gas when irradiated by a specific laser wavelength that causes the first glass substrate 302 and the second glass substrate 308 to lift-off. In other embodiments, mechanical debonding (i.e., peeling) may be used instead of a laser lift-off to remove the first glass substrate 302 and the second glass substrate 308. After removing the second glass substrate 308 using either laser lift-off or mechanical debonding, the flexible barrier film 100 left behind protects the OLED materials from oxygen and moisture. In certain exemplary embodiments, the flexible substrate 19 may be laminated to a support substrate, such as a plastic (e.g., PEN), metal, ceramic, organic-inorganic hybrid, or glass substrate (not shown).

It will be apparent to those skilled in the art that various modifications and variations can be made to embodiments of the present disclosure without departing from the spirit and scope of the disclosure. Thus it is intended that the present disclosure cover such modifications and variations provided they come within the scope of the appended claims and their equivalents.

What is claimed is:

1. A light extraction apparatus for a flexible organic light-emitting diode (OLED) display comprising:
a flexible substrate;
an OLED supported by the flexible substrate;
a flexible barrier film;
a tapered reflector comprising at least one side surface, a top surface coupled to the flexible barrier film, and a bottom surface, the top surface being larger in surface area than the bottom surface; and
an index-matching layer coupled between a top surface of the OLED and the bottom surface of the tapered reflector,
wherein light emitted from the top surface of the OLED passes through the index-matching layer and into the tapered reflector, and
wherein the at least one side surface of the tapered reflector comprises a slope to redirect the light by reflection into an escape cone and out of the top surface of the tapered reflector.

2. The light extraction apparatus of claim 1, wherein the tapered reflector comprises a truncated pyramid comprising a trapezoidal cross-section.

3. The light extraction apparatus of claim 1, wherein the flexible substrate comprises polyimide, polyethylene terephthalate (PET), or polycarbonate.

4. The light extraction apparatus of claim 1, wherein the flexible barrier film comprises a multi-layer film.

5. The light extraction apparatus of claim 1, wherein the flexible OLED display comprises an external light extraction efficiency greater than 40%.

6. The light extraction apparatus of claim 1, wherein the tapered reflector comprises a material formable by imprinting.

7. The light extraction apparatus of claim 1, wherein the light from the OLED comprises red light, green light, or blue light.

8. The light extraction apparatus of claim 1, further comprising:
at least one microlens embedded in the tapered reflector at the bottom surface of the tapered reflector.

9. The light extraction apparatus of claim 1, wherein a refractive index of the index-matching layer is greater than or equal to a refractive index of the tapered reflector.

10. The light extraction apparatus of claim 1, wherein the bottom surface of the tapered reflector comprises a surface area that is no more than 90% of the surface area of the top surface of the OLED.

11. A flexible organic light-emitting diode (OLED) display comprising:
a flexible substrate supporting an array of OLEDs, each OLED of the array of OLEDs having a top surface through which light is emitted;
an array of a tapered reflectors, each tapered reflector of the array of tapered reflectors aligned with an OLED of the array of OLEDs, and each tapered reflector of the array of tapered reflectors comprising at least one side surface, a top surface, and a bottom surface coupled to the top surface of a respective OLED of the array of OLEDs, the top surface of each tapered reflector being larger in surface area than the bottom surface of each tapered reflector; and
a flexible barrier film coupled to the top surface of each tapered reflector of the array of tapered reflectors.

12. The flexible OLED display of claim 11, further comprising:
an array of index-matching layers,
wherein an index-matching layer of the array of index-matching layers is coupled between the top surface of each OLED of the array of OLEDs and the bottom surface of each tapered reflector of the array of tapered reflectors.

13. The flexible OLED display of claim 12, wherein light emitted from the top surface of each OLED of the array of OLEDs passes through a corresponding index-matching layer of the array of index-matching layers and into a corresponding tapered reflector of the array of tapered reflectors, and
wherein the at least one side surface of each tapered reflector of the array of tapered reflectors comprises a slope to redirect light by reflection into an escape cone and out of the top surface of the corresponding tapered reflector.

14. The flexible OLED display of claim 11, wherein the top surface of each tapered reflector of the array of tapered reflectors includes an outer edge, and
wherein the outer edges of adjacent tapered reflectors of the array of tapered reflectors are arranged immediately adjacent to one another.

15. The flexible OLED display of claim 11, wherein each tapered reflector of the array of tapered reflectors comprises a truncated pyramid comprising a trapezoidal cross-section.

16. A method for fabricating a flexible organic light-emitting diode (OLED) display, the method comprising:
applying a first release layer on a first glass substrate;
applying a flexible substrate on the first release layer;
forming an array of OLEDs on the flexible substrate;
applying a second release layer on a second glass substrate;
applying a flexible barrier film on the second release layer;
forming an array of tapered reflectors on the flexible barrier film, each tapered reflector of the array of tapered reflectors comprising at least one side surface, a top surface coupled to the flexible barrier film, and a bottom surface, the top surface being larger than the bottom surface; and
applying the second substrate, the second release layer, the flexible barrier film, and the array of tapered reflectors to the array of OLEDs such that the bottom surface of each tapered reflector of the array of tapered reflectors is coupled to an OLED of the array of OLEDs.

17. The method of claim 16, further comprising:
releasing the first release layer to separate the first glass substrate from the flexible substrate; and
releasing the second release layer to separate the second glass substrate from the flexible barrier film.

18. The method of claim 17, wherein releasing the first release layer comprises irradiating the first release layer with a laser, and
releasing the second release layer comprises irradiating the second release layer with a laser.

19. The method of claim 17, further comprising:
laminating the flexible substrate to a support substrate.

20. The method of claim 16, further comprising:
applying an index-matching layer between each OLED of the array of OLEDs and the bottom surface of each tapered reflector of the array of tapered reflectors.
